(19) United States
(12) Patent Application Publication
(10) Pub. No.: US 2026/0234784 A1
(43) Pub. Date: Aug. 13, 2026

(54) SURFACE-COATED CUTTING TOOL

(71) Applicants: Oerlikon Surface Solutions AG, Pfäffikon, Pfäffikon (CH); Mitsubishi Materials Corporation, Tokyo (JP)

(72) Inventors: Volker DERFLINGER, Feldkirch (AT); Denis KURAPOV, Walenstadt (CH); Derya KAYA BUERZLE, Balzers (LI); Yuto SUGAWARA, Tokyo (JP); Shun SATO, Tokyo (JP)

(21) Appl. No.: 19/474,675

(22) PCT Filed: Apr. 11, 2024
(86) PCT No.: PCT/EP2024/059892

§ 371 Date: Oct. 10, 2025

(30) Foreign Application Priority Data
Apr. 13, 2023 (JP) 2023-065856

(51) Int. Cl. C23C 14/06

(52) U.S. Cl. CPC C23C 14/0641; C23C 14/0652

(57) ABSTRACT

A surface-coated cutting tool having a substrate and a hard coating film formed on the surface of the substrate, wherein the hard coating film has a lower layer made of AlCrXZ film, an intermediate layer consisting of alternating laminated films of layer A made of AlCrX′Z film and layer B made of AlCrBWX″Z film, and an upper layer made of TiSiX′″Z film, the lower layer and the intermediate layer have crystalline structures preferentially oriented in the (111) plane of the face-centered cubic structure, and the upper layer has a crystalline structure preferentially oriented in the (200) plane of the face-centered cubic structure.

This patent application claims the benefits of Japanese Patent Application No. 2023-065856, filed on Apr. 13, 2023, the entire contents of which are hereby expressly incorporated by reference.

The present invention relates to a surface-coated cutting tool.

### STATE OF THE ART

As conventional hard coatings for cutting tools, alternating-layer films of an AlCrN film and an AlCrBN film and alternating-layer films of an AlCrBWN film and an AlCrN film are known, for example from documents WO 2016/102170 A1 and WO 2008/037556 A1. However, for example, when conventional hard coatings were used on small-diameter tools with tool diameters of 3 mm or less, it could be observed that surface smoothing by post-treatment is difficult, and sufficient tool life is not achieved.

### OBJECTIVE OF THE PRESENT INVENTION

Thus, it is an object of the present invention to alleviate or to overcome one or more difficulties related to the prior art. In particular, it is an object of the present invention to provide a surface-coated cutting tool that can be easily post-treated and that is sufficiently resistant, even for small workpiece diameters.

### DESCRIPTION OF THE PRESENT INVENTION

According to the present disclosure, a surface-coated cutting tool having a substrate and a hard coating film formed on the surface of the substrate, wherein the hard coating film has a lower layer formed on the substrate, an intermediate layer formed on the lower layer and consisting of alternating laminated films of layer A and layer B, and an upper layer formed on the intermediate layer, the lower layer is a layer having an average composition satisfying 0.30≤a≤0.50 and 0≤b≤0.05 in a compositional formula of (Al_{1-a-b}CrₐX_{b})Z (X is one or more elements selected from W, Mo, Ta, Zr and Nb, and Z is one of N, C, CN, NO, CO and CNO), the layer A of the intermediate layer is a layer having an average composition satisfying 0.30≤c≤0.50 and 0≤d≤0.05 in a compositional formula of (Al_{1-c-d}Cr_{c}X′_{d})Z (X′ is one or more elements selected from W, Mo, Ta, Zr and Nb, and Z is one of N, C, CN, NO, CO and CNO), the layer B of the intermediate layer is a layer having an average composition satisfying 0.30≤e≤0.50, 0.01≤f≤0.15, 0.01≤g≤0.15, and 0≤h≤0.05 in a compositional formula of (Al_{1-e-f-g-h}CrₑB_{f}W_{g}X″ₕ)Z (X″ is one or more elements selected from Mo, Ta, Zr and Nb, and Z is one of N, C, CN, NO, CO and CNO), the upper layer is a layer having an average composition satisfying 0.15≤i≤0.35, 0≤j≤0.05 in a compositional formula of (Ti₁₋ᵢ₋ⱼSiᵢX′″j)Z (X′″ is one or more elements selected from Al, Cr, Zr, B and W, and Z is one of N, C, CN, NO, CO and CNO), Each of the lower layer and the intermediate layer has a crystalline structure preferentially oriented in the (111) plane of the face-centered cubic structure, and the upper layer has a crystalline structure preferentially oriented in the (200) plane of the face-centered cubic structure.

Preferably, a ratio of X-ray diffraction peak intensities of the (200) and (111) planes of the upper layer, I(200)/I(111), may be between 10 and 200, and/or a ratio of X-ray diffraction peak intensities of the (200) and (111) planes summarizing the lower layer and the intermediate layer, I(200)/I(111), may be between 0.01 and 0.50.

Moreover, the thickness of the lower layer may be 0.1 μm or more and 6.0 μm or less, and/or the thickness of layer A of the intermediate layer may be 3 nm or more and 100 nm or less, and/or the thickness of the layer B of the intermediate layer may be 3 nm or more and 100 nm or less, and/or the overall thickness of the intermediate layer may be 0.5 μm or more and 16.0 μm or less, and/or the thickness of the upper layer may be 0.1 μm or more and 6.0 μm or less, and/or the overall thickness of the hard coating film may be 0.5 μm or more and 20.0 μm or less.

Furthermore, the arithmetic mean roughness Ra of the surface of the hard coating film may be 0.1 μm or less.

As could be shown, a surface-coated cutting tool according to the invention, shows excellent tool life abilities, even for small-diameter tools.

### DETAILED DESCRIPTION

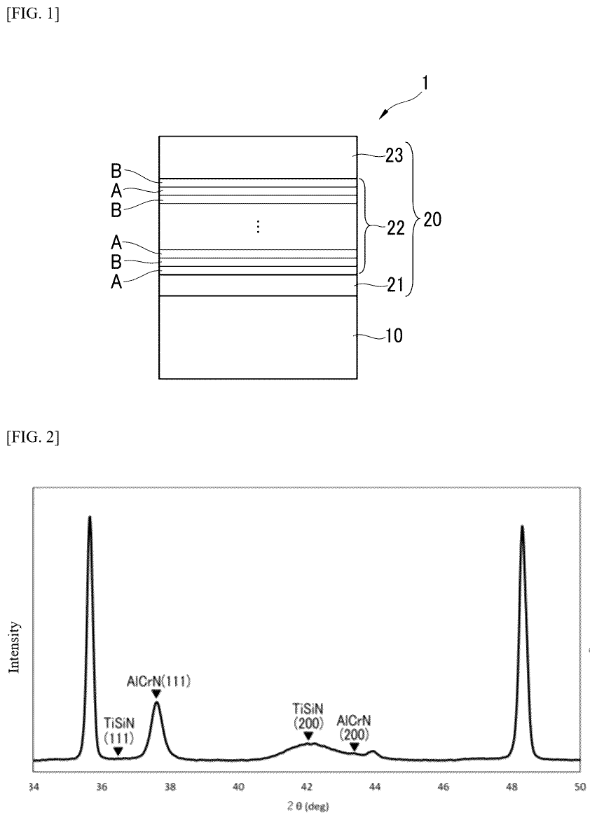

FIG. 1 shows a schematic diagram of the cross-sectional structure of the surface-coated cutting tool of an embodiment of the invention.

FIG. 2 shows an example of the X-ray diffraction profile of the surface-coated cutting tool of the embodiment according to FIG. 1.

The following is a detailed description of the surface-coated cutting tool according to an embodiment of the invention.

In this specification and the claims, when a numerical range is expressed as “L to M” (L and M are both numerical values), the range includes an upper limit (M) and a lower limit (L), and the units for the upper limit (M) and lower limit (L) are the same.

FIG. 1 is a schematic diagram showing the cross-sectional structure of the surface-coated cutting tool of an embodiment of the invention.

The Surface-coated cutting tool 1 of the present embodiment has a base 10 and a hard coating film 20 formed on the surface of the base 10. The hard coating film 20 has a lower layer 21 made of AlCrXZ (X is one or more elements selected from W, Mo, Ta, Zr and Nb, and Z is one of N, C, CN, NO, CO and CNO) film formed on the substrate 10, an intermediate layer 22 made of alternating layers of an layer A made of AlCrX′Z (X′ is one or more elements selected from W, Mo, Ta, Zr and Nb, and Z is one of N, C, CN, NO, CO and CNO) film and a layer B made of AlCrBWX″Z (X″ is one or more elements selected from Mo, Ta, Zr and Nb, and Z is one of N, C, CN, NO, CO and CNO) film formed on the lower layer 21, and an upper layer 23 made of TiSiX′″Z (X′″ is one or more elements selected from Al, Cr, Zr, B and W, and Z is one of N, C, CN, NO, CO and CNO) film formed on the intermediate layer 22.

The component Z included in the composition of each layer, any one of N, C, CN, NO, CO and CNO can be arbitrarily arranged as the component Z for each layer. Therefore, the components selected as Z in each layer may be different from each other. For example, the lower layer 21 may be made of an AlCrN film (Z=N) and the upper layer 23 may be made of a TiSiCNO film (Z=CNO).

Various conventionally known tool substrates can be used for the substrate 10. For example, cemented carbides (WC-based cemented carbides, those containing Co in addition to WC, including those to which carbides such as Ti, Ta, and Nb are added, etc.), cermets (those mainly composed of TiC, TiN, TiCN, etc.), ceramics (titanium carbide, silicon carbide, silicon nitride, aluminum nitride, aluminum oxide, etc.), cBN sintered materials, etc. aluminum oxide, etc.), cBN sintered body, etc. can be used.

The hard coating film 20 may include layers other than the lower 21, intermediate 22, and upper 23 layers. For example, a layer may be formed between the lower layer 21 and the substrate 10 to improve adhesion between the lower layer 21 and the substrate 10. For example, another layer consisting of nitride or carbonitride may be formed on top of the upper layer 23.

The overall thickness of the hard coating film 20 is 0.5 μm or more and 20.0 μm or less. If the overall thickness of the hard coating film 20 is less than 1.0 μm, it is difficult to obtain sufficient wear resistance over a long period of time. If the overall thickness of the hard coating film 20 exceeds 20.0 μm, abnormal damage such as chipping and peeling is likely to occur. The overall thickness of the hard coating film 20 is preferably 0.7 μm or more, or 0.9 μm or more. The overall thickness of the intermediate layer 22 is preferably 15.0 μm or less, 10.0 μm or less, or 5.0 μm or less.

The lower layer 21 of the hard coating film 20 is a composite compound layer of Al, Cr and X having an average composition satisfying the compositional formula: (Al_{1-a-b}CrₐX_{b})Z (X is one or more elements selected from W, Mo, Ta, Zr, and Nb, and Z is one of N, C, CN, NO, CO and CNO), wherein 0.30≤a≤0.50 and 0≤b≤0.05. The lower layer 21 is preferably a composite nitride layer of Al and Cr.

Al improves high-temperature hardness and heat resistance, while Cr improves high-temperature strength and improves high-temperature oxidation resistance in the coexistence of Cr and Al. When the a value (atomic ratio), which indicates the Cr content ratio, is less than 0.30, due to the increase in the relative Al content ratio and the appearance of grains with a hexagonal crystal structure, hardness and wear resistance are reduced. On the other hand, when the a value (atomic ratio) exceeds 0.50, sufficient high-temperature hardness and heat resistance cannot be ensured due to the relative decrease in the Al content ratio, and wear resistance is reduced.

The a value is preferably 0.33 or more, or 0.35 or more. The a value is preferably 0.47 or less, or 0.45 or less.

The lower layer may contain the element X. X is one or more elements selected from W, Mo, Ta, Zr and Nb. The range of the content ratio of X (the b value) is 0 or more and 0.05 or less in atomic ratio. The hardness and oxidation resistance (oxidation onset temperature) of the film are improved by adding the element X. The element X can be added to the extent that it does not adversely affect the properties of the hard coating film. The b value is preferably 0.02 or more. The b value is preferably 0.04 or less.

The thickness of the lower layer 21 is preferably 0.1 μm or more and 6.0 μm or less. When the film thickness of the lower layer 21 is less than 0.1 μm, it is difficult to obtain sufficient wear resistance over a long period of time. When the film thickness of the lower layer 21 exceeds 6.0 μm, abnormal damage such as chipping and peeling is likely to occur. The film thickness of the lower layer 21 is preferably 0.15 μm or more, or 0.2 μm or more. The thickness of the lower layer 21 is preferably 4.0 μm or less, 2.0 μm or less, or 1.0 μm or less.

The layer A of the intermediate layer 22 is a composite compound layer containing Al, Cr and X′ having an average composition satisfying the compositional formula: (Al_{1-c-d}Cr_{c}X_{d})Z (X′ is one or more element selected from W, Mo, Ta, Zr and Nb, and Z is one of N, C, CN, NO, CO and CNO) wherein 0.30≤c≤0.50 and 0≤d≤0.05. The reason for setting the c value in the above range is the same as the reason for setting the a value described above.

The c value is preferably 0.33 or more, or 0.35 or more. The b value is preferably 0.47 or less, or 0.45 or less. The layer B is preferably a composite nitride layer of Al and Cr.

The layer A may contain the element X′. X′ is one or more elements selected from W, Mo, Ta, Zr and Nb. The range of the content ratio of X′ (the d value) is 0 or more and 0.05 or less in atomic ratio. The hardness and oxidation resistance (oxidation onset temperature) of the film are improved by adding the element X′. The element X′ can be added to the extent that it does not adversely affect the properties of the hard coating film. The d value is preferably 0.02 or more. The d value is preferably 0.04 or less.

The layer B of the intermediate layer 22 has an average composition satisfying the compositional formula: (Al_{1-e-f-g-h}CrₑB_{f}W_{g}X″ₕ)Z (X″ is one or more elements selected from Mo, Ta, Zr and Nb, and Z is one of N, C, CN, NO, CO and CNO), wherein 0.30≤e≤0.50, 0.01≤f≤0.15, 0.01≤g≤0.15, and 0≤h≤0.05. The reasons for setting the e value in the above ranges are the same as the reasons for setting the a value above.

The e value is preferably 0.33 or more, or 0.35 or more. The e value is preferably 0.47 or less, or 0.45 or less. The f value is preferably 0.03 or more, or 0.05 or more. The f value is preferably 0.12 or less, or 0.10 or less. The g value is preferably 0.03 or more, or 0.05 or more. The g value is preferably 0.12 or less, or 0.10 or less. The layer B is preferably a composite nitride layer of Al, Cr, B and W.

By setting the total content ratio of B (boron) in the above range, the hardness of the layer B can be increased. By setting the total content ratio of W in the above range, the crystallinity of layer B can be improved.

The total content ratio of B (boron) is preferably 0.03 or more, or 0.05 or more in atomic ratio. The total content ratio of B (boron) is preferably 0.12 or less, or 0.10 or less in atomic ratio. The total content ratio of W is preferably 0.03 or more, or 0.05 or more in atomic ratio. The total content ratio of W is preferably 0.12 or less, or 0.10 or less in atomic ratio.

The intermediate layer 22 is an alternating layered film consisting of a layer A made of AlCrX′Z film and a layer B made of AlCrBWX″Z film. The thickness per layer of layer A is preferably 3 nm or more and 100 nm or less. The thickness per layer of the layer B is preferably 3 nm or more and 100 nm or less. By setting the film thicknesses in these ranges, the lattice mismatch between the layers A and B can be mitigated, and the toughness of the alternating-layer film as a whole is improved, making it easier to obtain the effect of suppressing crack growth.

The thickness per layer of layer A is preferably 60 nm or less, 30 nm or less, or 10 nm or less. The thickness per layer of layer B is preferably 60 nm or less, 30 nm or less, or 10 nm or less.

The overall thickness of the intermediate layer 22 is preferably 0.5 μm or more and 16.0 μm or less. When the overall thickness of the intermediate layer 22 is less than 0.5 μm, it is difficult to obtain sufficient wear resistance over a long period of time. When the overall thickness of the intermediate layer 22 exceeds 16.0 μm, abnormal damage such as chipping and delamination is likely to occur.

The overall thickness of the intermediate layer 22 is preferably 0.8 μm or more, or 1.0 μm or more. The overall thickness of the intermediate layer 22 is preferably 10.0 μm or less, 5.0 μm or less, or 3.0 μm or less.

The layer B may contain the element X″. X″ is one or more elements selected from Mo, Ta, Zr, and Nb. The range of the content ratio of X″ (the h value) is 0 or more and 0.05 or less in atomic ratio. The hardness and oxidation resistance (oxidation onset temperature) of the film are improved by adding the element X″. The element X″ can be added to the extent that it does not adversely affect the properties of the hard coating film. The h value is preferably 0.02 or more. The d value is preferably 0.04 or less.

The upper layer 23 is a composite compound layer of Ti, Si and X′″ having an average composition satisfying the compositional formula: (Ti₁₋ᵢ₋ⱼSiᵢX′″ⱼ)Z (X′″ is one or more elements selected from Al, Cr, Zr, B and W, and Z is one of N, C, CN, NO, CO and CNO), wherein 0.15≤i≤0.35, 0≤j≤0.05. The chipping resistance of the hard coating film is improved by forming an upper layer 23 consisting of composite compound containing Ti, Si and X′″. When the i value is less than 0.15, the improvement in chipping resistance is less effective. When the i value exceeds 0.35, the lattice distortion increases and the upper layer 23 is more likely to delaminate.

The i value is preferably 0.18 or more, or 0.20 or more. The i value is preferably 0.32 or less, or 0.30 or less. The upper layer 23 is preferably a composite nitride layer containing Ti and Si.

The upper layer 23 may contain the element X′″. X′″ is one or more elements selected from Al, Cr, Zr, B and W. The range of the content ratio of X′″(the j value) is 0 or more and 0.05 or less in atomic ratio. The hardness and oxidation resistance (oxidation onset temperature) of the film are improved by adding the element X′″. The element X′″ can be added to the extent that it does not adversely affect the properties of the hard coating film. The d value is preferably 0.02 or more. The d value is preferably 0.04 or less.

The thickness of the upper layer 23 is preferably 0.1 μm or more and 6.0 μm or less. When the thickness of the upper layer 23 is less than 0.1 μm, it is difficult to obtain sufficient wear resistance over a long period of time. When the thickness of the upper layer 23 exceeds 6.0 μm, abnormal damage such as chipping and delamination is likely to occur. The thickness of the upper layer 23 is preferably 0.15 μm or more, or 0.2 μm or more. The thickness of the upper layer 23 is preferably 4.0 μm or less, 2.0 μm or less, or 1.0 μm or less.

In hard coating film 20, intermediate layer 22 has a face-centered cubic crystal structure, as identified by X-ray diffraction, with the crystal structure preferentially oriented in the (111) plane. The upper layer 23 has a face-centered cubic crystal structure as identified by X-ray diffraction, with the crystal structure preferentially oriented in the (200) plane.

Normally, when a TiSiX′″Z film is formed on the intermediate layer 22, which is preferentially oriented in the (111) plane. In the present disclosure, the upper layer 23 preferentially oriented in the (200) plane is formed on the intermediate layer 22 preferentially oriented in the (111) plane by controlling the deposition equipment and deposition conditions when depositing the upper layer 23 made of TiSiX′″Z film. As a result, the upper layer 23 can be composed of a TiSiX′″Z film with excellent hardness and thermal conductivity, and a surface-coated cutting tool with excellent chipping resistance and wear resistance can be obtained.

In the lower layer 21 and intermediate layer 22, the ratio of the X-ray diffraction peak intensity I(200) of the (200) plane summarizing the layers 21 and 22 to the X-ray diffraction peak intensity I(111) of the (111) plane summarizing the layers 21 and 22, I(200)/I(111), is preferably 0.01 or more and 0.50 or less.

In the upper layer 23, the value of the ratio I(200)/I(111) between the X-ray diffraction peak intensity I(200) of the (200) plane and the X-ray diffraction peak intensity I(111) of the (111) plane is preferably 10 or more and 200 or less.

The intermediate layer 22 preferentially oriented in the (111) plane has excellent hardness. The wear resistance of the margin is improved when used as a drill. The upper layer 23 preferentially oriented in the (200) plane has excellent thermal conductivity. The heat resistance of the rake face of the tool is improved.

The hard coating film 20 according to the present embodiment has a very smooth surface. Specifically, in the surface-coated cutting tool of the present embodiment, the arithmetic mean roughness Ra of the hard coating film 20 surface is 0.1 μm or less. Thereby, friction with the work material is reduced and the wear resistance of the hard coating film 20 is improved.

The composition and thickness of each layer constituting the hard coating film 20, as well as the thickness of each layer of the alternating-layer film and the total thickness, can be measured by cross-sectional measurement of a longitudinal section of the hard coating film perpendicular to the substrate surface using scanning electron microscopy (SEM), transmission Electron Microscope (TEM), and cross-sectional measurements using Energy Dispersive X-ray Spectroscopy (EDS) can be made on the longitudinal section of the hard film perpendicular to the substrate surface.

The surface of the substrate is defined as the reference line of interface roughness between the substrate and the hard coating film in the observed image of the cross section. When the substrate has a planar surface like an insert, elemental mapping using EDS is performed on the longitudinal section. The interface between the lower layer 21 and the substrate is defined by performing known image processing on the obtained elemental map. An average line is calculated arithmetically for the resulting roughness curve of the interface between the lower layer 21 and the tool substrate. The obtained average line is determined as the surface of the substrate. The direction perpendicular to this average line is defined as the direction perpendicular to the substrate.

Even if the substrate has a curved surface like a drill, if the tool diameter is sufficiently large with respect to the thickness of the hard coating film, the interface between the hard coating film and the substrate in the measurement area will be planar. Since the interface is substantially planar, the surface of the substrate can be determined in a similar manner. That is, for example, in the case of a drill, elemental mapping using EDS is performed on a longitudinal section of the hard coating film perpendicular to the axial direction. And the obtained elemental map is subjected to known image processing to determine the interface between the lower layer and the substrate. The average line of the roughness curve of the interface between the lower layer 21 and the substrate is calculated arithmetically, thus this is used as the surface of the substrate. The direction perpendicular to the average line is defined as the direction perpendicular to the substrate.

In addition, the measurement area in the longitudinal section is set so as to include the entire thickness area of the hard coating film. Considering the measurement accuracy of the total film thickness of the hard coating film and the thickness of individual layer, it is preferable to observe and measure a plurality of fields (for example, 3 fields) with a field of view of about 10 μm×10 μm.

In addition, the layer A and the layer B have repeated changes in the B concentration or W concentration. Therefore, B concentration or W concentration in each layer is measured by multiple analysis lines (for example, 5 lines). The position where the B concentration and W concentration appear and each becomes 1 atomic % is defined as the interface with the adjacent layer, the obtained values of layer thickness are averaged to obtain the average layer thickness.

Since the lower layer 21 and the upper layer 23 are single layers, respectively, each of the average thickness is obtained by averaging the thicknesses of the layer measured on a plurality of analysis lines.

The crystalline structure of each layer comprising the hard coating film 20 can be measured using X-ray diffraction (XRD) and electron backscattered diffraction (EBSD).

The crystal structure of each layer forming the hard coating film 20 can be confirmed by electron beam diffraction using a transmission electron microscope (TEM). Specifically, the crystal structures of each of the lower layer 21, the intermediate layer 22 and the upper layer 23 are identified to confirm that they are NaCl-type face-centered cubic structures.

X-ray diffraction uses Cu-Kα rays and is measured by the 2θ/θ concentration method. FIG. 2 shows an example of the X-ray diffraction profile of the surface-coated cutting tool of the embodiment. The 111 diffraction-line summarizing the lower layer 21 and the intermediate layer 22 is near 37.5 degrees, the 111 diffraction line of the upper layer 23 is near 36.5 degrees, and the 200 diffraction line summarizing the lower layer 21 and the middle layer 22 is near 43.5 degrees, and the 200 diffraction line of the upper layer 23 is confirmed at around 42 degrees. The peaks around 36 and 48 degrees are attributed to hexagonal WC.

The arithmetic mean roughness Ra of the surface of the hard coating film can be measured according to JIS B-0601 (2001) using a laser microscope (e.g. VK-X3000 manufactured by Keyence).

### Examples

As substrates, WC cemented carbide drill substrates with tool diameters of φ0.8 mm and 2.0 mm were prepared.

Hard coating films of the composition shown in Table 1 below were formed on the above drill substrates.

### Examples

In the invention examples, a sputtering apparatus capable of simultaneous sputtering of three different target materials was used. Among these deposition sources, an AlCr alloy target, an AlCrBW alloy target, and a TiSi alloy target were installed in the apparatus as deposition sources. The drill substrate was secured to the sample holder in the sputtering apparatus and a bias power supply was connected to the drill substrate. The bias power supply has a structure that applies a negative bias voltage to the substrate independently of the target. The tool was put into the tool fixture enables three-fold rotation around its own axis. Ar and N₂ were used as introduced gases, and were introduced from a gas supply port provided in the sputtering apparatus.

### <Bombard Treatment>

First, before coating the drill substrate with the hard coating film, the drill substrate was bombarded by the following procedure. Heating was performed for 30 minutes while the temperature in the chamber was 430° C. by the heater in the sputtering apparatus. After that, the inside of the chamber of the sputtering apparatus was evacuated to a pressure of 5.0×10⁻³ Pa or less. Then, Ar gas was introduced into the chamber of the sputtering apparatus, and the pressure in the chamber was adjusted to 0.7 Pa. Then, a DC bias voltage of −200 V was applied to the drill substrate, and the drill substrate was cleaned (bombarded) with Ar ions.

### <Deposition of Lower Layer 21>

A coating of AlCrN was then applied on the tool by the following procedure. While maintaining the chamber temperature at 430° C., 360 sccm of Ar gas was introduced into the chamber of the sputtering apparatus, and then 330 sccm of N₂ gas was introduced to set the pressure in the chamber to 0.75 Pa. A DC bias voltage of −40 V was applied to the drill substrate, and the discharge time per cycle of the power applied to the alloy target containing Al and Cr was set to 0.2 milliseconds. A continuous power application resulted in lower layer approximately 0.2 μm thick on the surface of the drill substrate.

### <Deposition of Intermediate Layer 22>

A hard coating film was then applied over the lower layer 21 by the following procedure.

While maintaining the chamber temperature at 430° C., 360 sccm of Ar gas was introduced into the chamber of the sputtering apparatus, and then 380 sccm of N₂ gas was introduced to set the pressure in the chamber to 0.70 Pa. A DC bias voltage of −50 V was applied to the drill substrate, and the discharge time per cycle of the power applied to the alloy target containing Al and Cr and the alloy target containing Al, Cr, B and W was 0.2 milliseconds. Electric power was applied simultaneously to AlCr-based alloy targets and to the AlCrBW-based alloy targets to form the intermediate layer having a thickness of about 1.5 μm on the lower layer 21.

### <Deposition of Upper Layer 23>

Next, a hard coating film was applied onto the intermediate layer 22 by the following procedure.

While maintaining the chamber temperature at 430° C., 360 sccm of Ar gas was introduced into the chamber of the sputtering apparatus, and then 170 sccm of N₂ gas was introduced to set the pressure in the chamber to 0.55 Pa. A DC bias voltage of −70 V is applied to the drill substrate, and the discharge time per cycle of the power applied to the alloy target containing Ti and Si is 4.5 milliseconds to form upper layer having a thickness of about 0.2 μm on the intermediate layer 22.

### Comparative Examples

For samples Nos. 5 to 10, which are comparative examples, hard coating films were deposited on the surface of the drill substrate by adjusting the film formation time so as to obtain the film thicknesses shown in Table 1 below using the same apparatus, bombardment treatment conditions, and film deposition conditions as in samples Nos. 1 to 4 which are invention examples.

Also, for samples Nos. 11 to 13, hard coating films were deposited under the same conditions as 1 to 4 except of changing the composition of the alloy target and adjusting the conditions so as to obtain the film thicknesses shown in Table 1.

TABLE 1

| | Lower Layer | | Intermediate Layer | | | | | Upper Layer | | | |
|---|---|---|---|---|---|---|---|---|---|---|---|
| | | Thick- | | Thick- | Layer A | LayerB | | | Thick- | | |
| | | ness | | ness | Thickness | Thickness | I (200)/ | | ness | I (200)/ | Ra |
| No | Compositon | (mm) | Compositon | (mm) | (nm) | (nm) | I(111) | Compositon | (mm) | I(111) | (mm) |
| 1 | (A10. 60Cr0. | 0. 2 | (A10. 57Cr0. 31B0. | 1.5 | 5.0 | 4.5 | 0. 025 | (Ti0. 75Si0. | 0. 2 | 40 | 0. 03 |
| | 40) N | | 10W0. 02)N | | | | | 25) N | | | |
| | | | /(A10. 60Cr0. 40) N | | | | | | | | |
| 2 | (A10. 50Cr0. | 0. 5 | (AI0. 60Cr0. 30B0. | 3.0 | 32.4 | 63.4 | 0. 019 | (Ti0. 85Si0. | 1.0 | 98 | 0. 06 |
| | 50) N | | 05W0. 05)N | | | | | 15) N | | | |
| | | | /(AI0. 50Cr0. 50) N | | | | | | | | |
| 3 | (A10. 70Cr0. | 1.0 | (A10. 53Cr0. 35B0. | 0. 8 | 52.3 | 28.5 | 0. 194 | (Ti0. 70Si0. | 3.0 | 154 | 0. 05 |
| | 30) N | | 03W0. 09)N | | | | | 30) N | | | |
| | | | /(AIO. 70Cr0. 30) N | | | | | | | | |
| 4 | (A10. 60Cr0. | 0. 7 | (A10. 50Cr0. 40B0. | 1.4 | 49.6 | 12.8 | 0. 021 | (Ti 0. 65Si0. | 2.2 | 123 | 0. 05 |
| | 40) N | | 06W0. 04)N | | | | | 35) N | | | |
| | | | /(A10. 60Cr0. 40) N | | | | | | | | |
| 5 | (A10. 60Cr0. | 1.5 | — | — | — | — | 0. 230 | (Ti0. 85Si0. | 2.7 | 146 | 0. 04 |
| | 40) N | | | | | | | 15) N | | | |
| 6 | (A10. 50Cr0. | 3.8 | — | — | — | — | 0. 220 | — | — | — | 0. 02 |
| | 50) N | | | | | | | | | | |
| 7 | — | — | (A10. 57Cr0. 31B0. | 4.3 | 5.3 | 6.5 | 0. 013 | — | — | — | 0. 07 |
| | | | 10W0. 02)N | | | | | | | | |
| | | | /(A10. 60Cr0. 40) N | | | | | | | | |
| 8 | — | — | | — | — | — | — | (Ti0. 70Si0. | 3.5 | 182 | 0. 07 |
| | | | | | | | | 30) N | | | |
| 9 | (A10. 70Cr0. | 0. 3 | (A10. 53Cr0. 35B0. | 2.2 | 18.6 | 37.1 | 0. 016 | — | — | — | 0. 03 |
| | 30) N | | 03W0. 09)N | | | | | | | | |
| | | | (A10. 70Cr0. 30) N | | | | | | | | |
| 10 | (A10. 60Cr0. | 0. 8 | (A10. 60Cr0. 35B0. | 2.4 | 21.0 | 59.8 | 0. 018 | — | | — | 0. 04 |
| | 40) N | | 05) N | | | | | | | | |
| | | | /(A10. 60Cr0. 40) N | | | | | | | | |
| 11 | (A10. 80Cr0. | 0. 5 | (AI0. 57Cr0. 31B0. | 1.5 | 152.6 | 168.5 | 0. 027 | (Ti0. 70Si0. | 0. 3 | 55 | 0. 04 |
| | 20) N | | 10W0. 02)N | | | | | 30) N | | | |
| | | | /(A10. 80Cr0. 20) N | | | | | | | | |
| 12 | (A10. 60Cr0. | 1.9 | (A10. 45Cr0. 45B0. | 0. 8 | 42.3 | 30. 0 | 0. 184 | (Ti0. 85Si0. | 1.0 | 100 | 0. 06 |
| | 40) N | | 05W0. 05)N | | | | | 15) N | | | |
| | | | /(AI0. 60Cr0. 40) N | | | | | | | | |
| 13 | (A10. 70Cr0. | 0. 4 | (AI0. 53Cr0. 35B0. | 1.0 | 2.8 | 3.5 | 0. 144 | (Ti0. 90Si0. | 2.5 | 130 | 0. 07 |
| | 30) N | | 03W0. 09)N | | | | | 10) N | | | |
| | | | (A10. 70Cr0. 30) N | | | | | | | | |

### (Evaluation)

Using the surface-coated cutting tool of each sample prepared, drilling was performed under the conditions shown in Table 2 below. Table 3 shows the tool life of each sample when the life of the reference sample, No. 5 surface-coated cutting tool, is set to 100. All of the samples (Nos. 1 to 4) of the invention examples were superior in tool life to the No. 5 sample in which a conventional coating without the intermediate layer was applied to a drill substrate having the same shape as those of the invention samples. In particular, Nos. 1 and 4 samples using drill substrates with tool diameters of φ0.8 mm had tool lives 200% or more of the conventional tool. Nos. 3 and 4 samples with tool diameters of φ2.0 mm had tool lives 200% or more of the conventional tool. On the other hand, Nos. 6 to 10 samples which were omitted some layers and Nos. 11 to 13 samples whose composition range are outside the scope of the present invention, were inferior to the No. 5 sample in tool life.

TABLE 2

| Tool Diameter | 0.8 | mm | 2.0 | mm |
|---|---|---|---|---|
| work material | JIS SCM440 | | ← | |
| Cutting speed Vc | 50.0 | m/min | ← | |
| feed fr | 0.025 | mm/rev | 0.06 | mm/rev |
| Depth of cut ld | 4 | mm | 14 | mm |
| Coolant | Water soluble | | ← | |
| Coolant pressure | 7 | Mpa(Internal) | 2 | Mpa(Internal) |

TABLE 3

| | | Performance (%) | |
|---|---|---|---|
| No | | Ø0.8 mm | Ø2.0 mm |
| 1 | Invention Example | 267 | 163 |
| 2 | Invention Example | 185 | 132 |
| 3 | Invention Example | 170 | 220 |
| 4 | Invention Example | 285 | 200 |
| 5 | Comparative Example | 100 | 100 |
| 6 | Comparative Example | 30 | 15 |
| 7 | Comparative Example | 80 | 65 |
| 8 | Comparative Example | 20 | 72 |
| 9 | Comparative Example | 75 | 80 |
| 10 | Comparative Example | 89 | 74 |
| 11 | Comparative Example | 66 | 63 |
| 12 | Comparative Example | 95 | 88 |
| 13 | Comparative Example | 55 | 40 |

### BRIEF DESCRIPTION OF THE REFERENCE SYMBOLS

1 . . . Surface-coated cutting tool, 10 . . . Substrate, 20 . . . Hard coating film, 21 . . . Lower layer,
22 . . . Intermediate layer, 23 . . . Upper layer

1. A surface-coated cutting tool having a substrate and a hard coating film formed on the surface of the substrate, wherein
the hard coating film has a lower layer formed on the substrate, an intermediate layer formed on the lower layer and consisting of alternating laminated films of layer A and layer B, and an upper layer formed on the intermediate layer,
the lower layer is a layer having an average composition satisfying 0.30≤a≤0.50 and 0≤b≤0.05 in a compositional formula of (Al_{1-a-b}CrₐX_{b})Z (X is one or more elements selected from W, Mo, Ta, Zr, and Nb, and Z is one of N, C, CN, NO, CO, and CNO),
the layer A of the intermediate layer is a layer having an average composition satisfying 0.30≤c≤0.50 and 0≤d≤0.05 in a compositional formula of (Al_{1-c-d}Cr_{c}X′_{d})Z (X′ is one or more elements selected from W, Mo, Ta, Zr, and Nb, and Z is one of N, C, CN, NO, CO, and CNO),
the layer B of the intermediate layer is a layer having an average composition satisfying 0.30≤e≤0.50, 0.01≤f≤0.15, 0.01≤g≤0.15, and 0≤h≤0.05 in a compositional formula of (Al_{1-e-f-g-h}CrₑB_{f}W_{g}X″ₕ)Z (X″ is one or more elements selected from Mo, Ta, Zr, and Nb, and Z is one of N, C, CN, NO, CO, and CNO),
the upper layer is a layer having an average composition satisfying 0.15≤i≤0.35, 0≤j≤0.05 in a compositional formula of (Ti₁₋ᵢ₋ⱼSiᵢX′″ⱼ)Z (X′″ is one or more elements selected from Al, Cr, Zr, B, and W, and Z is one of N, C, CN, NO, CO, and CNO),
each of the lower layer and the intermediate layer has a crystalline structure, and
the upper layer has a crystalline structure.

2. The surface-coated cutting tool according to claim 1,
wherein a ratio of X-ray diffraction peak intensities of the (200) and (111) planes of the upper layer, I(200)/I(111), is 10 or more and 200 or less, and
a ratio of X-ray diffraction peak intensities of the (200) and (111) planes summarizing the lower layer and the intermediate layer, I(200)/I(111), is 0.01 or more and 0.50 or less.

3. The surface-coated cutting tool according to claim 1,
wherein the thickness of the lower layer is 0.1 μm or more and 6.0 μm or less,
the thickness of layer A of the intermediate layer is 3 nm or more and 100 nm or less,
the thickness of the layer B of the intermediate layer is 3 nm or more and 100 nm or less,
the overall thickness of the intermediate layer is 0.5 μm or more and 16.0 μm or less,
the thickness of the upper layer is 0.1 μm or more and 6.0 μm or less, and
the overall thickness of the hard coating film is 0.5 μm or more and 20.0 μm or less.

4. The surface-coated cutting tool according to claim 1,
wherein the arithmetic mean roughness Ra of the surface of the hard coating film is 0.1 μm or less.

5. The surface-coated cutting tool according to claim 1,
wherein the crystalline structure of the lower layer and the intermediate layer is oriented in the (111) plane of the face-centered cubic structure.

6. The surface-coated cutting tool according to claim 1,
wherein the crystalline structure of the upper layer is oriented in the (200) plane of the face-centered cubic structure.

7. The surface-coated cutting tool according to claim 1,
wherein the substrate is made of cemented carbides, cermets, ceramics or cBN sintered materials.

8. The surface-coated cutting tool according to claim 1,
wherein the hard coating film includes an adhesion layer, wherein the adhesion layer is formed between the lower layer and the substrate.

9. The surface-coated cutting tool according to claim 1,
wherein the hard coating film includes a further layer formed on the top of the upper layer, wherein the further layer consists of nitride or carbonitride.

10. The surface-coated cutting tool according to claim 1,
wherein the hard coating film includes a further layer formed on the top of the upper layer, wherein the further layer consists of nitride or carbonitride.
